(19) United States
(12) Patent Application Publication
(10) Pub. No.: US 2011/0159214 A1
(43) Pub. Date: Jun. 30, 2011

(54) GOLD-COATED POLYSILICON REACTOR SYSTEM AND METHOD

(75) Inventors: Jeffrey C. Gum, Stevensville, MT (US); Chad Fero, Missoula, MT (US); Dan Desrosier, Missoula, MT (US)

(73) Assignee: GT SOLAR, INCORPORATED, Merrimack, NH (US)

(21) Appl. No.: 12/934,160

(22) PCT Filed: Mar. 26, 2009
(86) PCT No.: PCT/US09/38389

§ 371 Date: Feb. 17, 2011

Related U.S. Application Data
(60) Provisional application No. 61/039,756, filed on Mar. 26, 2008.

(51) Int. Cl. C23C 16/46; C23C 16/455; C23C 16/458; C23C 16/24

(52) U.S. Cl. 427/587; 118/725; 427/593

(57) ABSTRACT

A reaction chamber system, and related devices and methods for use in the system, are provided in which reduced power consumption can be achieved by providing a thin layer of gold on one or more components inside a reaction chamber. The reaction chamber system can be used for chemical vapor deposition. The gold coating should be maintained to a thickness of at least about 0.1 microns, and more preferably about 0.5 to 3.0 microns, to provide a suitable emissivity inside the reaction chamber, and thus reduce heat losses.

### CROSS-REFERENCE TO RELATED APPLICATION

This application claims priority to U.S. Provisional Application Ser. No. 61/039,756, filed on Mar. 26, 2008, the disclosure of which is expressly incorporated herein by reference in its entirety.

### BACKGROUND OF THE INVENTION

1. Field of the Invention

The subject invention is directed to systems and methods for increasing energy efficiency in chemical vapor deposition reactors. More particularly, the invention relates to systems and methods for reducing power consumption in chemical vapor deposition reaction chamber systems by coating the inside of a reaction chamber with a thin layer of gold to reduce emissivity.

2. Description of the Related Art

In semiconductor fabrication processes and photovoltaic applications utilizing processes such as chemical vapor deposition (CVD), materials can be heated in large furnaces or reaction chambers that require high voltages to achieve melting and/or deposition of various chemical agents. It is desirable to provide improved systems and methods for reducing heat loss due to radial emission of heat through the outer surface of the furnace or chamber.

The use of silver as a coating inside a reaction chamber is known. U.S. Pat. No. 4,173,944 to Koppl et al., for example, discloses the use of a silver-plated bell jar in order to prevent cracking or breaking of the bell jar and aid in sealing of the bell jar from external gases and internal coating. U.S. Pat. No. 4,173,944 also discloses that the silver-plated bell jar requires considerably less energy due to a high yield rate. However, because silver tarnishes, and thus requires refinishing, it is not preferable to utilize silver inside a reaction chamber, in order to avoid the need for periodic maintenance.

Also generally known is the use of gold as an external reflective coating on a CVD reaction chamber. U.S. Pat. No. 4,579,080 to Martin et al., for example, discloses a reaction chamber in which gold plating can be used as a reflector on exterior wall surfaces of the chamber. However, the Martin reference specifically discourages the use of gold on internal wall surfaces because of the potential for gold to be transferred to a wafer via vapor phase transfer, which could result in contamination of the wafer.

U.S. Pat. No. 4,938,815 to McNeilly discloses an arrangement including a pair of reaction chambers, and a heating apparatus configured to be received between the reaction chambers. The heating apparatus is arranged to be moveable into and out of an area between the reaction chambers so that a processing step can be carried out on a wafer. The silicon wafer of this system is heated either by conduction heating via a heat transfer medium provided in the heating apparatus, or by an external source in the form of radiant heat lamps. According to U.S. Pat. No. 4,938,815, a heat energy reflecting layer film or foil surface, such as gold, can be provided on an inner surface of one chamber for reflecting heat energy from the heating apparatus onto the front surface of the wafer, so that the temperature of the wafer is maintained substantially uniform through its volume. However, the reaction chamber disclosed in U.S. Pat. No. 4,938,815 is designed for large-scale growth of a wafer that surrounds a heating apparatus configured to be inserted and removed between the reaction chambers, and is not suitable for heating and deposition of polysilicon on silicon rods or filaments.

### SUMMARY OF THE INVENTION

The subject invention is directed to a reaction chamber system and related devices and methods for use in the system, in which reduced power consumption can be achieved by providing a thin layer of gold on one or more components inside a reaction chamber. According to the subject invention, a reaction chamber made of stainless steel, alloys, or other materials is coated with a thin layer of gold, preferably at least about 0.1 microns thick, and more preferably about 0.5 to 3.0 microns in thickness. The gold-coated reaction chamber preferably has a lower emissivity, as compared to a conventional stainless steel chamber, thus lowering emissivity of the chamber wall and reducing radiant heat losses. Preferably the reaction chamber is configured for use in a chemical vapor deposition (CVD) process, and in particular, is used for depositing polysilicon in the reaction chamber.

According to the subject invention, power savings of up to about 30% can be achieved by use of a gold-coated reaction chamber, as compared to conventional uncoated stainless steel reaction chambers. For example, by using a gold coating of at least about 0.1 microns thick, or more preferably about 0.5 to 3.0 microns in thickness inside the chamber, power savings of about 20% to 30% are achievable. Although a gold coating has been found to be suitable if at least about 0.1 microns thick, other thicknesses can be used. In particular, the gold coating should have sufficient thickness to achieve the desired optical properties of low emissivity and high reflectivity. Therefore, if such properties can be obtained with a gold coating thickness below about 0.1 microns, a lower thickness could be utilized in a reaction chamber of the subject invention. Preferably, the gold coating has one or more characteristics such as good adhesion, cohesion, washability, and repairability. The more preferred range of between about 0.5 to 3.0 microns is selected based on a gold coating sufficient to maintain the desired optical properties, and where the surface preferably is substantially uniform.

While the primary function of the gold coating is to reduce the emissivity and increase the reflectivity of the reaction chamber and reactor internal components so that radiant heat losses are minimized, other advantages and benefits are provided. The systems and methods of the subject invention further can provide decreased heat flux, increased power savings, decreased component operating temperatures, and decreased corrosion of the inner surface of the chamber. As a result of this decreased corrosion, the quality of polysilicon produced can be improved because fewer corrosion products are available to contaminate the polysilicon. In addition, because less power is lost radiantly, less power is necessary to maintain silicon rod temperatures. Moreover, with decreased component temperatures, thermal stresses are reduced and equipment lifetimes can be increased.

The subject invention relates to systems and methods for reducing power consumption in a chemical vapor deposition polysilicon reaction chamber system. A chemical vapor deposition reactor system of the subject invention preferably includes a reaction chamber having at least a base plate fixed within the reaction chamber and an enclosure operably connected to the base plate. At least a portion of the reaction chamber is coated with a layer of gold having a thickness of at least about 0.1 microns, and more preferably about 0.5 to 3.0 microns. The base plate may also be similarly coated with gold for an additional power savings. One or more filaments preferably are attached to the base plate within the chamber upon which various reactant gases are deposited during a chemical vapor deposition cycle. The filament can be made of silicon or another desired solid to be fabricated. At least one gas inlet and one gas outlet are connected to the reaction chamber to allow gas flow through the reaction chamber. A window portion for viewing an internal portion of the chamber also can be provided. An electrical current source preferably is connected to ends of the filament via electrical feedthroughs in the base plate for supplying a current to heat the filament directly during a CVD reaction cycle. A cooling system for lowering a temperature of the chemical vapor deposition system also can be employed having at least one fluid inlet and at least one fluid outlet.

These and other aspects and advantages of the subject invention will become more readily apparent from the following description of the preferred embodiments taken in conjunction with the drawings.

### BRIEF DESCRIPTION OF THE DRAWINGS

So that those skilled in the art to which the subject invention appertains will readily understand how to make and use the method and device of the subject invention without undue experimentation, preferred embodiments thereof will be described in detail herein below with reference to certain figures, wherein:

FIG. 1 is a perspective view of a polysilicon reaction chamber system according to a preferred embodiment of the subject invention;

FIG. 2 is an interior perspective view of the polysilicon reaction chamber system of FIG. 1; and

FIG. 3 is a graph illustrating the power savings of a gold-coated chamber of the subject invention versus a conventional uncoated stainless steel chamber.

### DETAILED DESCRIPTION OF THE INVENTION

Preferred embodiments of the subject invention are described below with reference to the accompanying drawings, in which like reference numerals represent the same or similar elements.

A reaction chamber system, and related devices and methods for use with the system, are provided. The system preferably incorporates a chemical vapor deposition (CVD) reactor, in which polysilicon or another material can be deposited according to the Siemens method. Preferably the system includes a reaction chamber, in which existing power supplies are used. The chamber is used to deposit polysilicon on thin rods or filaments preferably made of silicon, which are heated by passing a current through the thin rods or filaments. The polysilicon deposits accumulate substantially uniformly on exposed surfaces of the filaments within the chamber, substantially without impurities. Alternatively, a material other than polysilicon can be deposited in the reaction chamber.

During deposition of polysilicon, trichlorosilane reacts with hydrogen and thin rods or silicon tube filaments to form polysilicon deposits on the thin rods or filaments. The subject invention is not restricted to CVD reactors using polysilicon deposition involving a reaction of trichlorosilane but can be used for reactions involving silane, dichlorosilane, silicon tetrachloride, or other derivatives or combinations of gases, for example, by using thin rods or filaments with large surface area geometries and similar electrical resistivity properties in accordance with the invention. Filaments of various shapes and configurations can be utilized, for example, those disclosed in U.S. Patent Application Publication US 2007/0251455, which is incorporated by reference herein.

The subject invention provides a gold-coated polysilicon chamber system having the advantage of reduced emissivity as compared to conventional stainless steel reaction chambers, which can have an emissivity of as low as 0.13. Specifically, highly polished stainless steel chamber surfaces may have an emissivity of about 0.13, but the emissivity of stainless steel quickly degrades over a period of a few months, and polishing of the surface is necessary to maintain an emissivity of about 0.13. Therefore, it would be desirable to utilize surfaces inside the reaction chamber with low emissivity and which do not require polishing or maintenance. Such a surface can be achieved by use of gold coatings according to the subject invention. Moreover, because gold surfaces require no refinishing, the use of a gold coating is advantageous as compared to other coatings such as silver.

According to the subject invention, power savings of up to about 30% can be achieved by use of a gold-coated reaction chamber, as compared to conventional uncoated stainless steel reaction chambers. For example, by using a gold coating of at least about 0.1 microns thick, or more preferably about 0.5 to 3.0 microns in thickness inside the chamber, power savings of about 20 to 30% are achievable. The more preferred range of gold coating thicknesses is about 0.5 microns to 3.0 microns, where the lower end of the range (about 0.5 microns) is selected based on a gold coating known to have sufficient thickness to achieve the desired optical properties of low emissivity and high reflectivity. Therefore, if such properties can be obtained with a gold coating thickness of below 0.5 microns, or even below about 0.1 microns, this lower thickness could be utilized in a reaction chamber of the subject invention. The higher end of the more preferred range of gold coating thickness (about 3.0 microns) is selected based on a gold coating sufficient to maintain the desired optical properties. In thicker coatings above about 3.0 microns, the surface may be non-uniform, and more expensive to produce due to the use of additional gold material. However, if substantially uniform gold coatings can be obtained above 3.0 microns in thickness, such coatings could be utilized with the subject invention. For example, larger thicknesses of the gold coating could be used if the gold coating is subsequently polished to ensure a substantially uniform surface.

One source of power savings resulting from the gold coating of the subject invention is a decrease in operating temperatures, specifically, a lower chamber wall temperature achievable during the cooling process. For example, in one embodiment, the rod surface temperature can be approximately 1100 degrees C., where rod surface temperatures can range from about 600 to 1300 degrees C. according to the subject invention. The bulk gas temperature in the reactor can be about 150 to 850 degrees C. In a conventional stainless steel chamber, the wall temperature when cooled by cooling water would be start at approximately 115 degrees and increase to approximately 185 degrees C. at the end of a cycle. However, in the gold coated chamber of the subject invention, the temperature of the chamber wall can be reduced to approximately 165 degrees C., thus potentially yielding power savings.

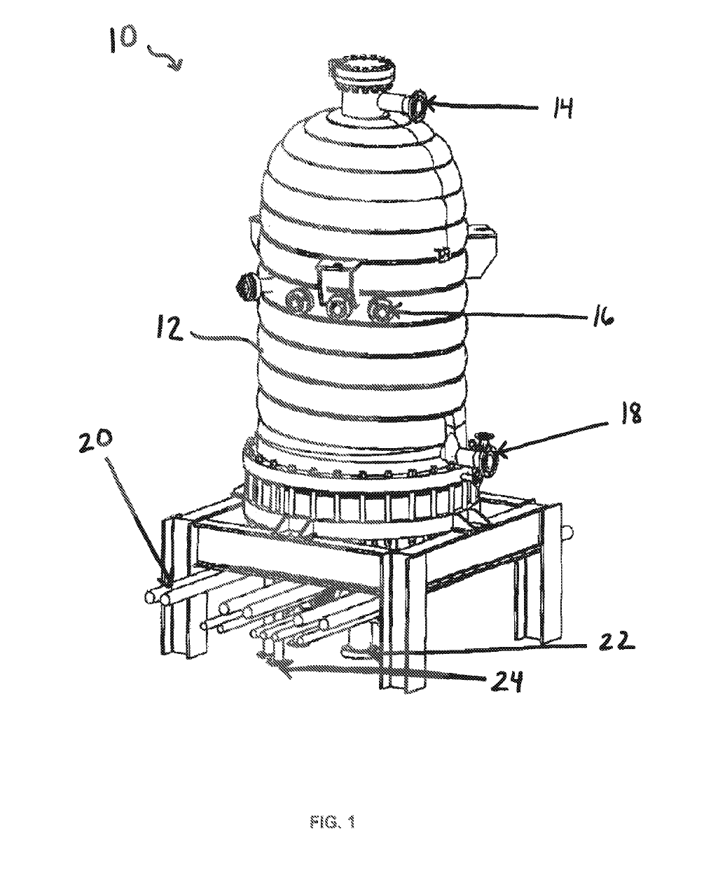

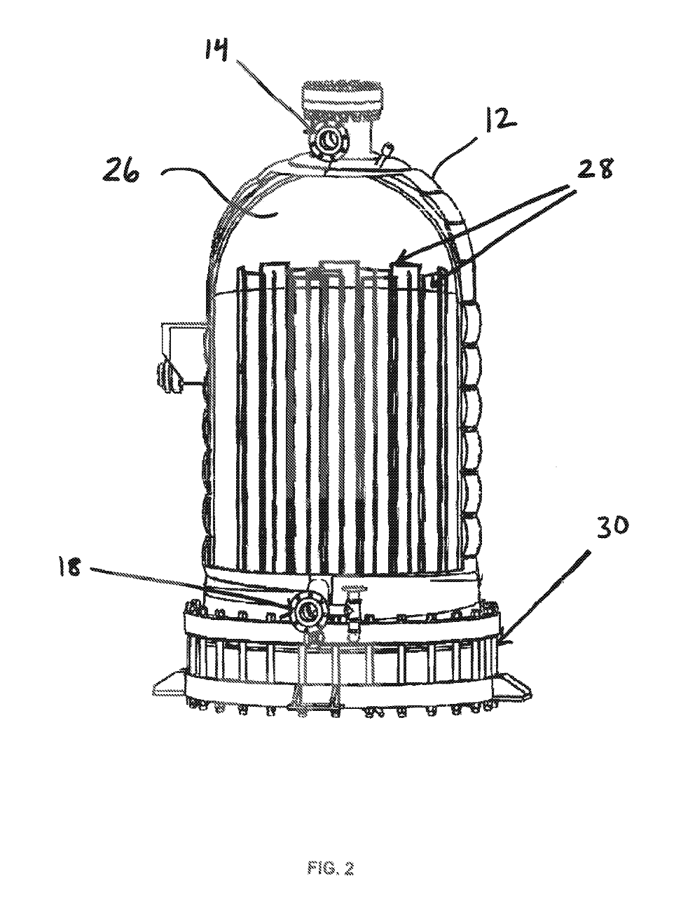

Referring to FIGS. 1 and 2, a chemical vapor deposition (CVD) reactor is shown, in which polysilicon is deposited onto thin rods or filaments according to the subject invention. In particular, referring to FIG. 2, an inner wall of a reaction chamber 12 can be coated with a thin layer of gold 26. The gold coating preferably is at least about 0.1 microns thick, or more preferably about 0.5 to 3.0 microns, although smaller or larger thicknesses can be used if the gold-coated chamber has suitable optical properties of low emissivity and high reflectivity. Emissivity ranges of about 0.01 to 0.12 have been found to provide increased power savings relative to stainless steel chambers according to the subject invention.

According to the subject invention, the chamber 12 incorporates a thin layer of gold 26 having an emissivity ranging from about 0.01 to 0.12, more preferably in a range of about 0.01 to 0.08. Optimally, the chamber 12 of the subject invention incorporating the thin layer of gold 26 has an emissivity ranging from about 0.01 to 0.03, which can result in substantial power savings of about 20% to 30% as compared to conventional uncoated stainless steel chambers. In particular, use of the gold coating can substantially reduce emissivity, and thus increase reflectivity in the reaction chamber, so that radiant heat losses are minimized. Increased power savings can therefore result in lower operating costs.

FIGS. 1 and 2 show the basic elements of a reactor system 10, for example, a polysilicon CVD reactor system including the reaction chamber 12. The chamber 12 preferably includes a base plate 30, a gas inlet nozzle 24, a gas outlet nozzle 22, and electrical feedthroughs or conductors 20 for providing a current to directly heat one or more filaments 28 within the chamber 12. A fluid inlet nozzle 18 and a fluid outlet nozzle 14 are connected to a cooling system for providing fluid to the reaction chamber 10. In addition, a viewing port 16 or sight glass preferably allows visual inspection of the interior of the reaction chamber 12, and can optionally be used to obtain temperature measurements inside the reaction chamber 12.

According to a preferred embodiment of the subject invention as depicted in FIGS. 1 and 2, the reaction chamber 12 has a gold-coated inner chamber wall (where the gold coating is designated by reference number 26), and the reactor system is configured for bulk production of polysilicon. The system further includes the base plate 30 that may, for example, be a single plate or multiple opposing plates, preferably configured with filament supports, and an enclosure attachable to the base plate 30 so as to form a deposition chamber. As used herein, the term “enclosure” refers to an inside of the reaction chamber 12, where a CVD process can occur.

One or more silicon filaments 28 preferably are disposed within the reaction chamber 12 on filament supports (not shown), and an electrical current source is connectable to both ends of the filaments 28 via electrical feedthroughs 20 in the base plate 30, for supplying a current to directly heat the filaments. Further provided is at least one gas inlet 24 in the base plate 30 connectable to a source of silicon-containing gas, for example, and a gas outlet 22 in the base plate 30 whereby gas may be released from the chamber 12.

In operation, the reactor system of the subject invention can be used to deposit polysilicon on filaments 28 and/or rods arranged in the reaction chamber 12, for example, in a manner similar to that disclosed in U.S. Ser. No. 11/413,425, published as U.S. Patent Pub. No. 2007/0251455, which is incorporated by reference herein in its entirety. In U.S. Patent Pub. No. 2007/0251455, thin rods or filaments inside the chamber are configured on filament supports, and an electrical current source is connectable to each filament via electrical feedthroughs in the base plate system for heating the filament. In accordance with the subject invention, polysilicon can be deposited on filaments or rods in the manner described in U.S. Patent Pub. No. 2007/0251455.

According to additional preferred embodiments of the subject invention, a gold coating can be provided not only on the interior surface of the chamber itself, but also on the surface of various other components contained within the chamber including, but not limited to: gas inlet nozzle 24, gas outlet nozzle 22, additional flanges, sidewalls of the viewing port 16, the base plate 30, and other gas flow distribution components within the reactor. These coatings preferably are also at least about 0.1 microns thick, and more preferably about 0.5 to 3.0 microns in thickness, and in particular, are applied at a suitable thickness to provide desirable optical properties and thus achieve the low emissivity and high reflectivity necessary to reduce energy costs. The coatings described herein act as a heat shield for structures inside the reaction chamber 12. Because the surface of the gold coating 26 reflects the majority of the radiant heat flux to the surface of a particular component, the overall heat flux to that component is drastically reduced as the radiant heat makes up approximately one-half of the overall heat flux in the reaction chamber. A reduced heat flux to components inside the reaction chamber can result in greatly reduced operating temperatures. Because of the reduced heat flux, the reactor system 10 components such as the vessel wall, base plate 30, gas inlet and outlet nozzles 24, 22, flanges, as well as other system components undergo less thermal stress. The reduced operating temperature also provide the advantage of increasing the number of heat cycles a component can undergo which results in overall increase to the longevity of the system.

The gold-coated reaction chamber 12 of the subject invention also acts to reduce heat flux. With a large reduction in radiant heat that is absorbed into the vessel wall, for example, the wall temperatures are drastically reduced. In addition, operating with a lower vessel inner wall temperature allows raising the cooling fluid (e.g. water, heat transfer fluid) temperature to the chamber 12 so that the heat lost to the cooling fluid can be successfully recovered for use elsewhere in the system 10 providing further energy savings. This can be done in a reaction chamber made of stainless steel, alloys, or other materials.

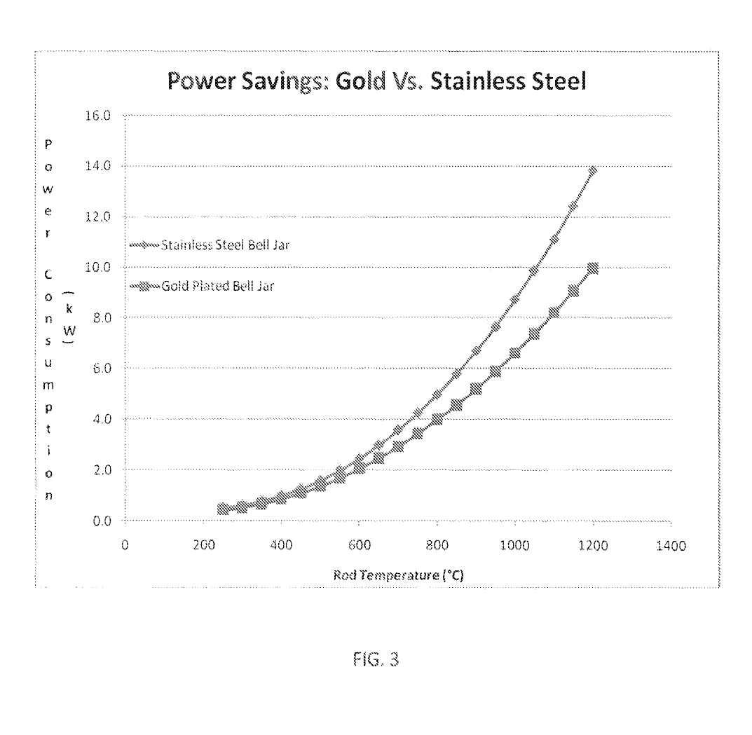

As shown in FIG. 3, the gold-coated chamber 12 of the subject invention can reduce the amount of power consumed relative to a conventional uncoated stainless steel chamber. As the silicon rod or filament temperatures within the gold-coated chamber 12 increase, the power savings can increase as well. Specifically, as more radiant energy in the appropriate wavelength range is emitted from the rod or filament surface, it is reflected back to the rod/filament by the gold coating. Thus, less energy input is needed to maintain the silicon rod/filament surface temperature, which can result in an overall increased savings on production costs.

The gold coating preferably also increases the polysilicon deposition rate on the rods/filaments. In a conventional stainless steel chamber, the temperature of the rods varies based on its proximity to the cooling element. Thus, in conventional applications, the area of the rod facing the cold wall, for example, is cooler than the inside of the rod. In the gold coated chamber of the subject invention, the temperature deviation of the rods/filaments is lower because the overall rod/filament temperature is increased, thereby allowing an increased deposition rate, higher yield, and overall increased productivity of the system.

A method for depositing a material in a reactor can include steps of: providing a reaction chamber including at least a base plate fixed within the reaction chamber and an enclosure operably connected to the base plate, at least a portion of the reaction chamber being coated with a layer of gold having a thickness of at least about 0.1 microns, and more preferably about 0.5 to 3.0 microns; attaching at least one filament to the base plate; connecting an electrical current source to the reaction chamber for supplying a current to the filament; connecting a gas source to the reaction chamber to allow gas flow through the reaction chamber; and operating the reactor to deposit the material on the filament in the reaction chamber. According to the subject invention, the material deposited on the filament can be polysilicon, and the filament can include silicon.

The subject invention is particularly configured for bulk polysilicon deposition, in which silicon rods or filaments arranged in a reactor are resistively heated by running an electrical current through the rods and/or filaments. In contrast, other arrangements, such as the reaction chambers disclosed in U.S. Pat. No. 4,938,815, utilize conduction and/or radiation to heat a silicon wafer. Such arrangements are not suitable for use in growing polysilicon on rods or filaments, at least because using conduction to heat silicon rods/filaments would cause one side of the rod/filament to be in direct contact with a heating source, which could prevent silicon deposition on the one side. Further, the use of radiative sources such as heat lamps would substantially prevent polysilicon deposition on rods/filaments, at least because when using radiant lamps, an external heating source must operate inside a reaction chamber; however, such lamps are not suitable because of high operating temperatures and an unsuitable chemical environment inside the reactor. Moreover, in order to evenly heat an individual rod/filament, several lamps would be required, which would result in a complex and expensive layout.

The subject invention can achieve benefits such as increased power savings, reduced operating temperatures, and reduced corrosion. Although the subject invention has been described with respect to preferred embodiments, those skilled in the art will readily appreciate that changes or modifications thereto may be made without departing from the spirit or scope of the subject invention as defined by the appended claims.

What is claimed is:

1. A reactor system, comprising:
a reaction chamber including at least a base plate fixed within the reaction chamber and an enclosure operably connected to the base plate, at least a portion of the reaction chamber being coated with a layer of gold having a thickness of at least about 0.1 microns;
at least one filament attached to the base plate;
an electrical current source for supplying a current to the filament; and
a gas source operably connected to the reaction chamber to allow gas flow through the reaction chamber.

2. The reactor system of claim 1, wherein the current is supplied directly to the filament through an electrical feedthrough in the base plate.

3. The reactor system of claim 1, wherein the reaction chamber further comprises a viewing port for viewing an internal portion of the reaction chamber.

4. The reactor system of claim 1, wherein the reaction chamber is coated with the layer of gold having a thickness of about 0.5 to 3.0 microns.

5. The reactor system of claim 1, wherein the at least one filament comprises silicon.

6. The reactor system of claim 1, further comprising a cooling system having at least a fluid inlet and a fluid outlet operably connected to the reactor system.

7. The reactor system of claim 1, wherein the reactor system is a chemical vapor deposition reactor system.

8. The reactor system of claim 1, wherein the reaction chamber coated with the layer of gold has an emissivity of between about 0.01 and 0.03.

9. A reaction chamber for use in a chemical vapor deposition reactor, comprising:
at least a base plate fixed within the reaction chamber;
at least one filament attached to the base plate, the reaction chamber being operably connected to an electrical current source and a gas source to allow deposition of a material on the filament; and
at least a portion of the reaction chamber being coated with a layer of gold having a thickness of at least about 0.1 microns.

10. The reaction chamber of claim 9, wherein a current is supplied to the filament by the electrical current source.

11. The reaction chamber of claim 10, wherein the current is supplied directly to the filament through an electrical feedthrough in the base plate.

12. The reaction chamber of claim 9, further comprising at least a gas inlet and a gas outlet operably connected to the reaction chamber to allow gas flow through the reaction chamber.

13. The reaction chamber of claim 9, further comprising a viewing port for viewing an internal portion of the reaction chamber.

14. The reaction chamber of claim 9, wherein the at least one filament comprises silicon.

15. The reaction chamber of claim 9, wherein the reaction chamber coated with the layer of gold has an emissivity of between about 0.01 and 0.03.

16. A method for depositing a material in a reactor, comprising the steps of:
providing a reaction chamber including at least a base plate fixed within the reaction chamber and an enclosure operably connected to the base plate, at least a portion of the reaction chamber being coated with a layer of gold having a thickness of at least about 0.1 microns;
attaching at least one filament to the base plate;
connecting an electrical current source to the reaction chamber for supplying a current to the filament;
connecting a gas source to the reaction chamber to allow gas flow through the reaction chamber; and
operating the reactor to deposit the material on the filament in the reaction chamber.

17. The method of claim 16, wherein the material deposited on the filament is polysilicon.

18. The method of claim 16, wherein the filament comprises silicon.

19. The method of claim 16, wherein the reactor is a chemical vapor deposition reactor.

20. The method of claim 16, further comprising the step of:
supplying the current directly to the filament through an electrical feedthrough in the base plate.

21. The method of claim 16, wherein the reaction chamber is coated with the layer of gold having a thickness of about 0.5 to 3.0 microns.

22. The method of claim 16, wherein the reaction chamber is coated with the layer of gold having an emissivity of between about 0.01 and 0.03.

23. The method of claim 16, wherein the reaction chamber further comprises a viewing port for viewing an internal portion of the reaction chamber.
